(19) United States
(12) Patent Application Publication
(10) Pub. No.: US 2024/0205636 A1
(43) Pub. Date: Jun. 20, 2024

(54) AUDIO DATA PROCESSING METHOD

(71) Applicant: PAOLO LUIGI COSI, LONDON (GB)

(72) Inventor: PAOLO LUIGI COSI, LONDON (GB)

(21) Appl. No.: 17/637,087

(22) PCT Filed: Aug. 28, 2020
(86) PCT No.: PCT/IB2020/058056

§ 371 Date: Mar. 16, 2022

(30) Foreign Application Priority Data
Aug. 29, 2019 (GB) 1912415.5

(51) Int. Cl. H04S 7/00; H03G 3/30

(52) U.S. Cl. CPC H04S 7/307; H03G 3/3005; H04S 7/301; H04S 7/303; H04S 2400/13

(57) ABSTRACT

There is provided a method of processing audio data for playback. The method comprises receiving (10) audio data defining a sound within a plurality of frequency bands; obtaining (30) a first equal loudness contour at a desired volume, obtaining (50) a second equal loudness contour at a listening volume; and modifying (60) the frequency balance of the audio data based on the difference between the first and second equal loudness contours in each frequency band, such that playing the audio data at the listening volume will cause the user to perceive the frequency balance of the sound to be as though the sound was being played at the desired volume. There is further provided an audio playback system comprising a processor for implementing the method, and an audio data signal for processing by the method.

### FIELD OF THE INVENTION

The present invention relates to an audio data processing method

### BACKGROUND OF THE INVENTION

Audio transducers such as speakers produce sounds, typically by playing back stored audio data. The way that the generated sounds are perceived by the user (listener) will depend on the volume of the sound, for example the sound pressure level which is normally measured in dB. This is because the sensitivity of the human ear across the frequency spectrum changes according to the volume of the sound.

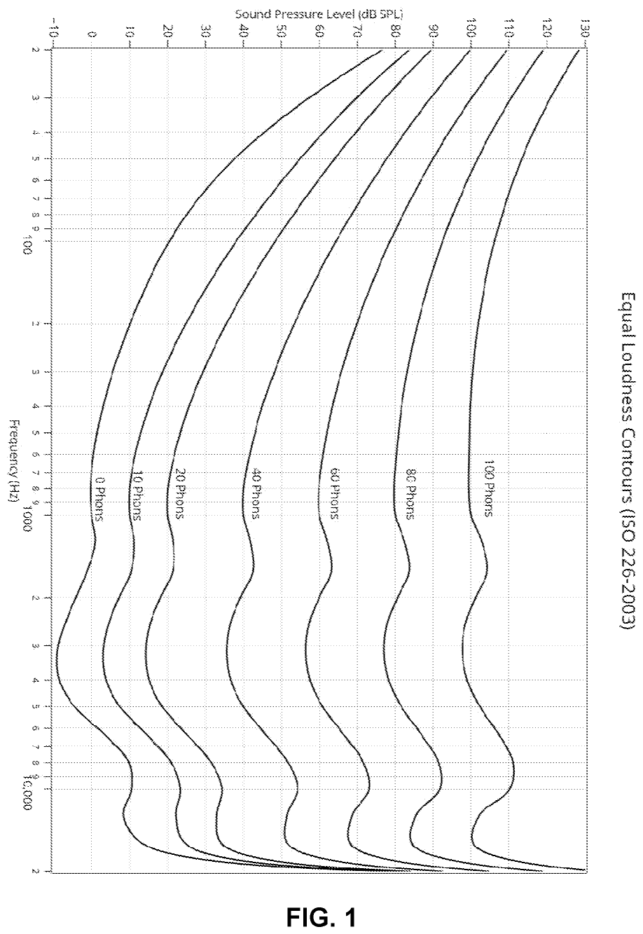

The sensitivity of the human ear across the frequency spectrum at different volume levels can be represented by equal loudness contours, often referred to as “Fletcher-Munson” curves after the earliest researchers on this subject. An equal loudness contour shows the sound pressure level required at each frequency for the human ear to perceive the sound pressure levels as having the same loudness as one another. For example, various equal loudness contours are defined in international standard ISO 226:2003, and each contour has a loudness rating in Phon, based on the sound pressure level at 1 kHz. A selection of these equal loudness contours are shown in FIG. 1. These equal loudness contours are based on the average young person's perception of sound, referenced to 1 kHz, and show that frequencies between 1 kHz and 5 kHz are perceived much more loudly than frequencies outside that range. The 0 dB (SPL) level corresponds to a sound pressure of 20 pPa, and the 94 dB (SPL) level corresponds to a sound pressure of 1 Pa, as is known in the art.

It can be seen in FIG. 1 that the ear's perception of loudness is flatter at higher volumes such as 100 Phon, than at lower volumes such as 10 Phon. Accordingly, the equal loudness contours show that the human ear is more sensitive to high and low frequencies at higher volume levels, than at lower volume levels. Therefore, the perceived frequency balance of a sound changes according to the volume of the sound, whilst the actual frequency balance of the sound remains the same. The frequency balance refers to the gain across the frequency spectrum, and may be conventionally altered by bass and treble controls, or an equalizer.

When audio data is played at low volume, the high (treble) and low (bass) frequencies are not perceived very well, and this encourages listeners to play back the audio data at much higher volumes so that the high and low frequencies can be strongly heard. However, this potentially exposes the listener to hearing damage, and so is undesirable. In addition, many audio transducers introduce significant distortion when sound is played back at high volumes, or result in excessive reverberation in enclosed listening spaces, and so the sound fails to be perceived as the producer intended.

When a very loud sound such as an explosion is recorded by a microphone, and later played back through a speaker, the perceived frequency balance of the played back sound will be the same as the frequency balance of the recorded frequencies at the microphone, only if the explosion is played back at the same volume as it was originally recorded at the microphone. Typically, explosions cannot be played back at the same high volume at which they were recorded, and so the high and low frequencies will appear subdued in comparison to the middle frequencies when the explosion is played back to the listener at a lower volume. Conversely, if a quiet sound such as distant birds tweeting is played back at a higher volume than was present at the microphone that recorded the sound, then the high and low frequencies will appear relatively louder upon playback than the middle frequencies.

Producers attempt to deal with this problem by making all the frequencies in the audio data appear with the correct loudnesses relative to one another when the audio data is played back at a particular volume level at which the producer intends the audio data to be played. In other words, the frequency balance will be perceived as the producer intends it to be perceived when the audio data is played back at the volume level intended by the producer. But, the producer has no control over the volume level that the listener actually selects, and the low and high frequencies will inevitably appear to be subdued or even absent if the listener selects a lower listening level than intended, or excessive if the listener selects a higher listening level than intended.

It is known in the art to provide a “loudness” button on high fidelity stereo systems, which performs a fixed alteration to the frequency spectrum when pressed, to help emphasise high (treble) and low (bass) frequency sounds when audio is listened to at low volume. However, this button is divorced from the actual volume of the audio, which can vary many times per second depending on the sounds being reproduced, and the button only ever applies a single alteration which is not accurate for the particular volume level that is set by the listener.

It is therefore an object of the invention to provide an audio data processing method that allows the relative loudnesses of different frequencies to be perceived according to the user or producer's specification, even if the audio data is played back at lower or higher volume levels than the producer intended.

### SUMMARY OF THE INVENTION

According to a first aspect of the invention, there is provided a method of processing audio data for playback, the method comprising:
receiving audio data defining a sound within a plurality of frequency bands;
obtaining a first equal loudness contour at a desired volume, the desired volume corresponding to a desired perceived frequency balance of the sound when listened to by a user;
determining a listening volume at which the user listens to the sound, obtaining a second equal loudness contour at the listening volume;
modifying the frequency balance of the audio data based on the difference between the first and second equal loudness contours in each frequency band, such that playing the audio data at the listening volume will cause the user to perceive the frequency balance of the sound to be as though the sound was being played at the desired volume; and outputting the modified audio data.

According to a second aspect of the invention, there is provided an audio processing system comprising an input for receiving audio data, a processor for performing the method of the first aspect, and an output for outputting the modified audio data.

Since the method takes into account the current listening volume of the user, by modifying the audio data according to the difference between equal loudness curves at the listening volume and the desired volume, the listener can perceive the frequency balance of the audio at the listening volume to be as though the audio was being played at the desired volume. Therefore, users no longer need to increase the listening volume to unsafe levels in order to hear the bass and treble frequencies of sounds clearly.

The method preferably comprises receiving the desired volume and obtaining the first equal loudness contour based on the desired volume. A memory may be used to store a plurality of equal loudness contours corresponding to different volumes, and interpolation between the equal loudness contours nearest to the desired volume then used to obtain the first equal loudness contour. Similarly, interpolation between the equal loudness contours nearest to the listening volume may be used to obtain the second equal loudness contour. Alternatively, each equal loudness contour may be generated by a mathematical model taking the desired volume or listening volume as an input.

The desired volume may be received as an input from the user, or it may be received as metadata accompanying the audio data. The producer of the audio data may define the desired volume using the metadata, so that the audio data will be perceived with the frequency balance that the producer intended, regardless of the listening volume that the user listens to the audio at. Therefore, according to a third aspect of the invention, there is provided an audio data signal comprising audio data defining a sound within a plurality of frequency bands, and metadata defining a desired volume at which the sound is to be listened at to provide a desired perceived frequency balance of the sound when listened to by a user.

The desired volume defined by the metadata may be time-varying through the duration of the sound, to indicate the volume that the sound is intended to be heard by the listener at each audio block in the audio stream, each audio block in the audio stream corresponding to a moment in time. The metadata may comprise different desired volumes for different sounds defined in the audio data, for example the sound of an explosion may have metadata specifying a high desired volume so that the low frequency rumble of the explosion can be heard at all listening levels, not just at high listening levels. Conversely, the sound of birds tweeting may have metadata specifying a low desired volume, so that the low and high frequency components of the sound are not perceived excessively strongly at higher listening levels. Equivalently, the metadata could specify the first equal loudness contour corresponding to the desired volume, instead of directly specifying the desired volume.

The audio data may define a plurality of sounds mixed for simultaneous playback, wherein the metadata comprises desired volumes for respective ones of the plurality of sounds. For example, the sound of a car driving past and the sound of a person speaking whilst the car drives past may each have their own metadata specifying the desired volume at which each of those sounds is intended to be reproduced. The desired volume may specify an absolute volume level, for example in metadata, or may be an offset in volume level compared to the determined listening volume, for example if a user wishes the perceived frequency balance to be as though the sound was being played a fixed amount higher than it is currently being played. If an absolute level is used, without any variation over time, then the perceived frequency balance of the sound is as though the sound always has a fixed volume, at the desired volume. However, since the volume of a sound typically varies in time, specifying the desired volume as a series of absolute values that vary in time with the amplitude of the audio data, or specifying the desired volume as a fixed offset in volume level above or below the listening volume, helps preserve the original dynamics of the sound as the absolute value of the desired volume moves up and down with the original volume of the sound.

Another application of the desired volume is to allow a sound object moving within a soundscape to have the correct perceived frequency balance relative to the listener as it moves. For example, the desired volume of an object in a computer game may be set to vary according to the position of the object relative to the listening position of a player in the game environment, so the change in the perceived frequency balance as the object moves provides a truer reflection of how the object would be heard by the player if the player was in real life rather than in a computer game.

The modification of the frequency balance of the audio data based on the difference between the first and second equal loudness contours in each frequency band, may comprise determining the difference between the first and second equal loudness contours at each of the frequency bands to produce a difference curve across the plurality of frequency bands; translating the difference curve towards a gain of one at a minimum or maximum point of the difference curve; and amplifying the audio data by the value of the translated difference curve at each frequency band to provide the modified audio data. Alternatively, the audio data may be amplified by the value of the difference curve at each frequency band, and then amplified across all frequency bands by the difference between the unity gain level and the minimum or maximum point of the difference curve. In practice, these steps may be implemented together with one another within a mathematical function.

Preferably, the difference curve is obtained by subtracting the first equal loudness contour from the second equal loudness contour. The subtraction produces a roughly U-shaped difference curve when the desired volume is greater than the listening volume, the U-shape being translated upward until its bottom reaches a gain of one. Accordingly, mid-range frequencies are left substantially the same and bass and treble frequencies are boosted when this translated difference curve is applied to the audio data. The subtraction produces a roughly f-shaped difference curve when the listening volume is greater than the desired volume, the f-shape being translated downward until its top reaches a gain of one. Accordingly, mid-range frequencies are left substantially the same and bass and treble frequencies are cut when this translated difference curve is applied to the audio data.

Equal loudness contours are typically expressed in the art on a scale of dB (SPL), and so translating the minimum or maximum point of the difference curve to the gain of one typically comprises translating the minimum or maximum point of the difference curve to 0 dB (SPL), and amplifying the audio data at each frequency band by the translated difference curve. It will be understood that amplification by a positive-valued dB level results in a boost in the amplitude of the audio signal at the corresponding frequency band, and that that amplification by a negative-valued dB level results in a cut in the amplitude of the audio signal at the corresponding frequency band.

The determination of the listening volume is important so that the correct second equal loudness curve can be obtained, so that the perceived frequency balance at the listening volume is correctly made to match the perceived frequency balance at the desired volume. The listening volume is the volume of the sound listened to by the user, which will vary according to the user's position relative to the sound transducers (for example speakers), and which is the cumulative result of all the frequencies that are being played at any given time. Preferably, the listening volume of the sound is the perceived listening volume, in other words the volume as perceived by the user, according to the user's perception of sound. An 80 dB (SPL) sound at a 20 Hz will be perceived to be much quieter than an 80 dB (SPL) sound at 1 kHz, and so commonly available sound level meters filter the sounds received by their microphone to provide an estimate of the volume of the sound as would be perceived by a user listening to that sound.

Since the user's perception of the relative loudnesses of different frequencies depends on how loud the sound is, the filtering that is applied by the sound meter depends on how loud the sound is. The standard IEC 61672-1:2013 mandates the use of a ‘C’ filter for measuring perceived listening volume of loud sounds, and an ‘A’ filter for measuring perceived listening volume of relatively quieter sounds. The ‘C’ filter is the inverse of a 100 Phon equal loudness contour, and the ‘A’ filter is the inverse of a 40 Phon equal loudness contour.

The perceived listening volumes provided by these sound meters are not entirely accurate, since a sound meter giving a sound meter result of 60 dB (SPL) will be filtered by the inverse of a 40 Phon equal loudness contour, corresponding to the ‘A’ filter, when it should be filtered by the inverse of a 60 Phon equal loudness contour for greater accuracy of measurement.

To allow the listening volume to be determined to a high accuracy, the determining of the listening volume in the present invention preferably comprises first carrying out a calibration step using a physical sound meter, to link the volume of an audio signal in the audio processing system to the listening volume of the sound heard by the user at the listening position. To do this, both the volume of the audio signal in the audio processing system and the listening volume need to be determined, to allow the differences between them to be determined. The volume of the audio signal in the audio processing system is a function of the amplitude of the audio data and the volume control setting of the audio processing system, and is preferably determined by a digital sound meter that receives the audio data and the volume control setting. The differences between the volume of the audio signal determined by the digital sound meter and the listening volume determined by the physical sound meter are used to help calibrate the digital sound meter, so that the digital sound meter will subsequently report the listening volume based on the volume of the audio signal, without needing the physical sound meter anymore

The audio signal measured by the digital sound meter may for example be an audio input signal at an input of the processing system, an audio output signal at an output of the audio processing system, or an audio signal within the audio processing system, provided that the amplitude of the audio data carried by the audio signal can be analysed together with the volume control setting of the audio processing system, to provide a volume that can be calibrated to the listening volume.

Preferably, during the calibration, noise having a known frequency spectrum is played through the audio processing system so that the offset between the volume of the audio signal measured by the digital sound meter and the listening volume measured by the physical sound meter can be obtained for each frequency band. The noise may for example be white, pink, or brown noise. The calibration may comprise playing a selection of frequencies through the audio processing system, monitoring the volumes of the sounds that are produced using the microphone of the physical sound meter, and storing a frequency response of the audio processing system. The physical sound meter may just comprise a single microphone placed at the listening position, however for improved accuracy it preferably comprises two microphones that are placed over the left and right ears of the listener when in the desired listening position of the room, allowing the perceived listening volumes at the listening position to be determined separately for each ear, and the digital sound meter to be calibrated to provide the perceived listening volumes for the left and right ears separately from one another. The two microphones may be arranged in a set of binaural microphones to be worn by the user when first setting up the system.

Once the calibration has been performed, the digital sound meter should correctly report the listening volume. The listening volume is preferably a perceived listening volume, and so the digital sound meter may filter the audio data by the inverse of an equal loudness contour to determine the perceived listening volume of the audio signal, and therefore determine the listening volume based on the calibration that was performed.

The listening volume is preferably the instantaneous volume of the sound listened to by the user, the listening volume varying over time in correspondence with the loudness of the sound defined by the audio data in each moment of time. The digital sound meter may analyse the amplitude of the audio data, and together with the inverse of the equal loudness contour and the volume control setting of the audio processing system, determine the perceived listening volume of the audio signal, and therefore the listening volume. The correct equal loudness contour to perform the volume measurement has to be selected based on an estimate of what the volume measurement will be, and so the correct equal loudness contour for a portion of the audio stream is estimated by dividing the audio data into identical first and second streams, applying a delay to the first stream, determining an equal loudness contour for the portion of audio data in the second stream during the delay, and filtering the portion of the audio data by the inverse of an equal loudness contour at the listening volume that was determined for the second stream. Since the volume of the audio data is continuously changing, to improve the accuracy of the correct equal loudness contour, the equal loudness contour to be applied to the audio data may be determined recursively. The recursion may comprise applying a first estimated equal loudness contour to a portion of the audio data to provide a first listening volume, selecting a second estimated equal loudness contour corresponding to the first listening volume, and applying the second estimated equal loudness contour to the portion of the audio data to provide a second listening volume, which should be more accurate than the first listening volume. The first estimated equal loudness contour may for example be the equal loudness contour that corresponds to the listening volume that was determined for the equivalent portion of the second undelayed audio stream.

Accordingly, the equal loudness contour that is chosen tracks the listening volume, and so the digital sound level meter can provide more accurate measurements of perceived listening volume compared to known physical sound meters that require user selection of a specific equal loudness contour from a very limited number of available equal loudness contours, e.g. corresponding to ‘A’ and ‘C’ filters as defined in IEC 61672-1:2013.

According to a fourth aspect of the invention, an audio processing system may therefore comprise an input for receiving audio data defining a sound, a volume control for setting a volume of the sound to be played back, and a digital sound meter for determining a perceived listening volume of the sound based on the audio data and the volume control setting, wherein the digital sound meter is configured to determine the perceived listening volume of the sound based on the audio data and the volume control setting by filtering the audio data by the inverse of an equal loudness contour corresponding to the perceived loudness that was determined by the digital sound meter for a portion of the audio data after splitting the audio data into first and second identical streams, applying a delay to the first stream, determining an equal loudness contour for the portion of audio data in the second stream during the delay, and filtering the portion of the audio data by the inverse of an equal loudness contour at the listening volume that was determined for the second stream and optionally recurring this process as described above. The digital sound meter of the fourth aspect of the invention may be the digital sound meter of the first to third aspects of the invention described above.

The equal loudness contours defined in the international standard ISO 226:2003 reflect the average perception of sound by a young and healthy person. However, perception of sound is different for different users, and also alters in dependence on the age of the user, for example due to hearing loss caused by old age. Therefore, the method may comprise determining equal loudness contours that are personal to the user, and storing the equal loudness contours in a memory. The first and second equal loudness contours, and/or the equal loudness contours used in the digital sound meter, may be obtained based on the equal loudness contours in the memory. For example, by interpolating between those equal loudness contours, or by storing the equal loudness contours in the memory in the form of a mathematical model that is based on the user's sense of hearing and that provides an equal loudness contour for any given volume level. The equal loudness curves personal to the user may for example be determined by performing otoacoustic emission tests on the user, or by for each equal loudness curve playing sounds of different frequencies to the user and receiving input from the user on which volumes the sounds need to be played at to be perceived at a same loudness to one another.

The perceived listening volume may be influenced by the modifications to the audio data that are made to cause the user to perceive the frequency balance of the sound to be as though the sound was being played at the desired volume, and so the accuracy of the digital sound meter may be improved by taking into account those modifications. Determining the listening volume may comprise modifying the frequency balance of the audio data based on the difference between the first and second equal loudness contours in each frequency band that was determined for a particular portion of the audio data.

When sounds are played at higher volumes, they are perceived to have greater reverberation, since the time required for the volume of the audio reflections to reduce to the level of the background audio noise (room tone) increases. To improve accuracy, this effect may be emulated both in the digital sound meter so that the perceived listening volume is more accurate, and in the modified audio data that is output from the audio processing system so that the sound will be perceived as though it is being played back at a higher (lower) desired volume. To emulate this effect, the reverberation added by the listening environment/room may be determined by measuring the impulse response of the listening environment/room. The audio data may be modified both in the digital sound meter and in the modified audio data that is output from the audio processing system by increasing (decreasing) reverberation by an amount based on a volume difference from the listening volume to the desired volume.

When sounds are played at higher volumes, audio processing systems often struggle to reproduce the sounds as accurately as they do at lower volumes, and harmonic distortion increases. This increase in harmonic distortion may be emulated both in the digital sound meter so that the perceived listening volume is more accurate, and in the modified audio data that is output from the audio processing system so that the sound will be perceived as though it is being played back at the desired volume. The harmonic distortion that is added by the audio processing system at higher listening volumes can also be measured by taking the impulse response of the listening environment/room. Then, the audio data to be measured by the digital sound meter and the modified audio data for output from the audio processing system are both modified to increase (decrease) harmonic distortion by an amount based on a volume difference from the listening volume to the desired volume. Harmonic distortion varies based on position of a transducer relative to a user's ear, and therefore in a preferred embodiment the distortion of each transducer in a sound system is determined independently, and determined for each ear of the user.

Since the modified audio data will have a different frequency balance to the unmodified audio data, the user may experience a change in perceived volume of the sound produced when the modification of the audio data begins, or when a significant change in the desired volume is made. In order for the user to perceive the sound produced after modification to be of the same volume level as the sound produced before modification, the method of the first aspect may comprise determining the listening volume both with and without modification of the frequency balance of the audio data based on the first and second equal loudness contours, determining a difference in volume between those two listening volumes, and altering an amplitude of the received audio data based on the difference in volume. Then, the change in perceived volume as a result of the modifications made to the frequency balance of the audio data will be greatly reduced.

For example, if the modified audio data is perceived to be louder than the unmodified audio data, then the volume of the input audio data is reduced by the difference between those volumes, so that the modified audio data is perceived by the listener to have a similar volume level as the unmodified audio data would have done. This may be particularly useful if the user sets the volume level at the maximum volume level they wish to hear, as then increases in perceived volume that would be caused by the modifications to the frequency balance of the audio data and that would cause the perceived volume level to rise beyond the maximum volume level set, are compensated for to keep the perceived volume at the maximum volume level and avoid hearing damage.

### DETAILED DESCRIPTION

Embodiments of the invention will now be described by way of non-limiting example only and with reference to the accompanying drawings, in which:

FIG. 1 shows a graph of equal loudness curves according to international standard ISO 226:2003;

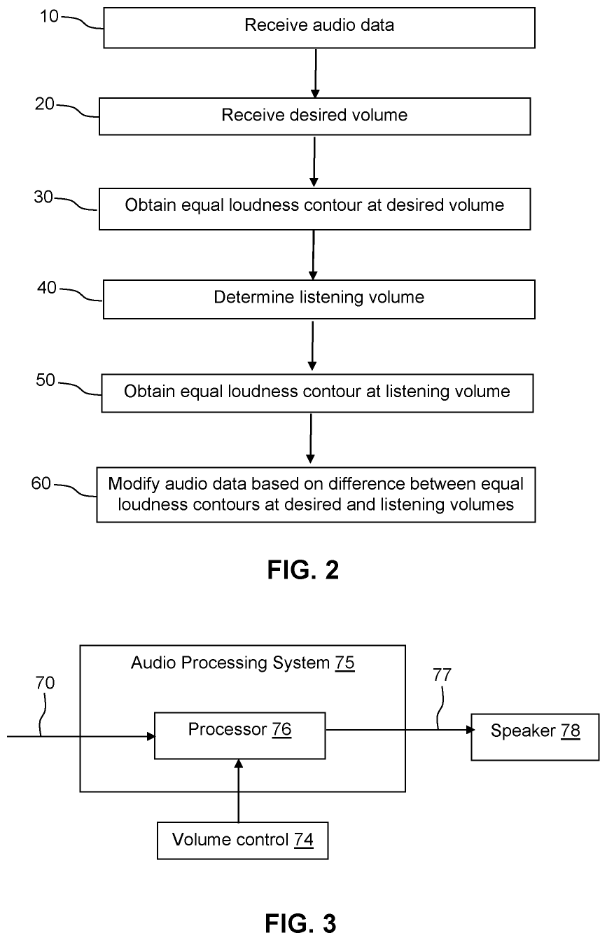

FIG. 2 shows a flow diagram according to an embodiment of the invention;

FIG. 3 shows a schematic diagram of an audio processing system according to an embodiment of the invention;

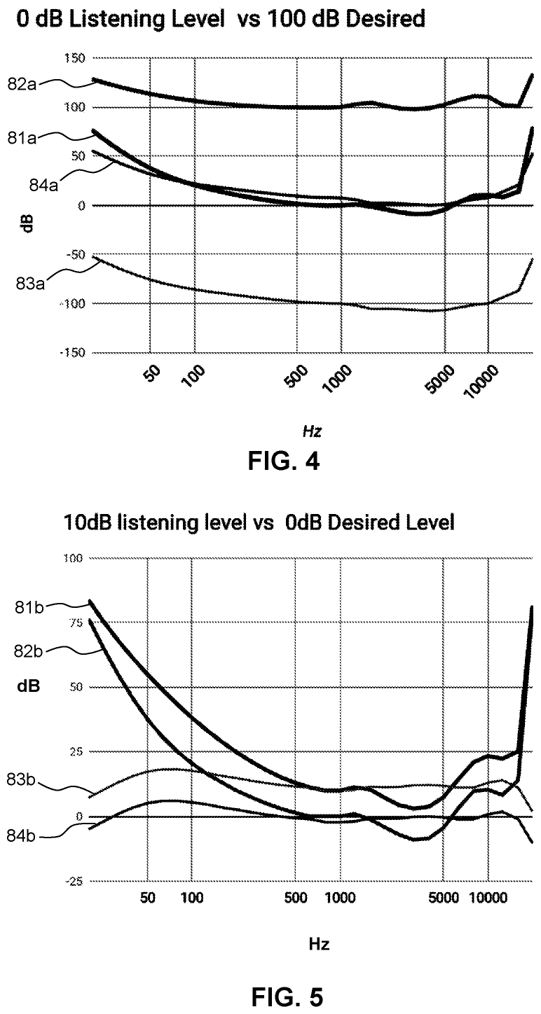

FIG. 4 shows a graph illustrating modifications to be made to the audio data in a case where the listening volume is lower than the desired volume;

FIG. 5 shows a graph illustrating modifications to be made to the audio data in a case where the listening volume is higher than the desired volume;

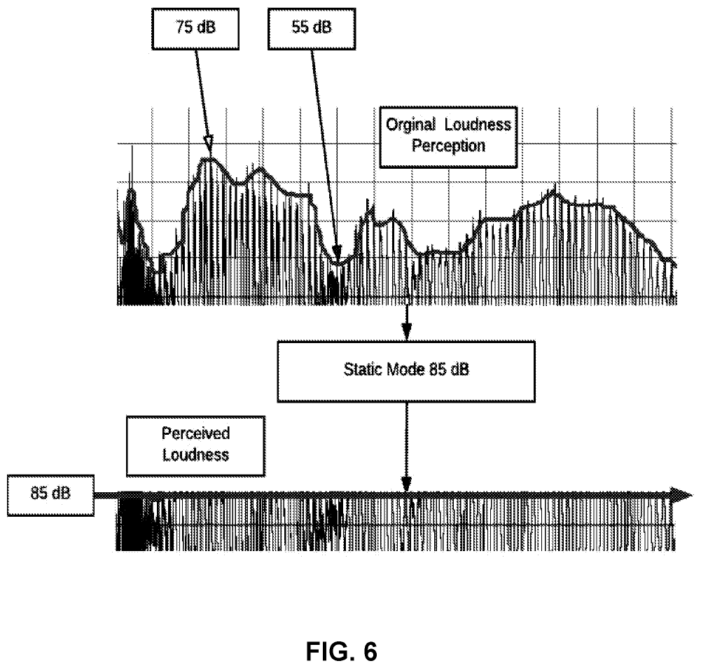

FIG. 6 shows graphs illustrating applying the desired volume in a static mode;

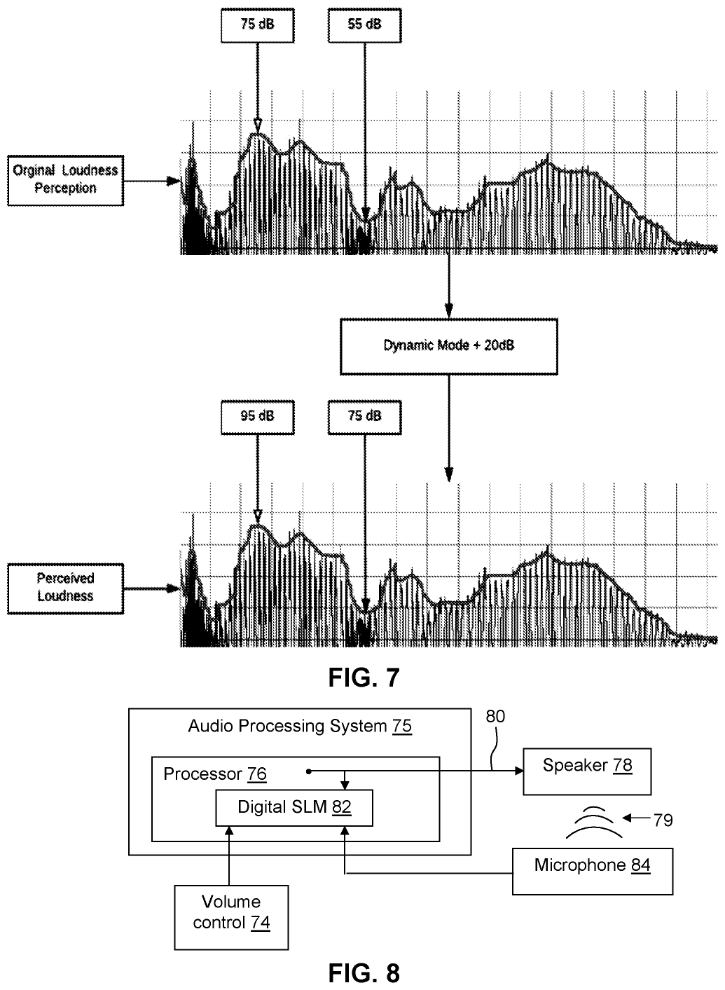

FIG. 7 shows graphs illustrating applying the desired volume in a dynamic mode;

FIG. 8 shows a more detailed schematic diagram of the audio processing system of FIG. 3 when being used to calibrate a digital sound meter; and

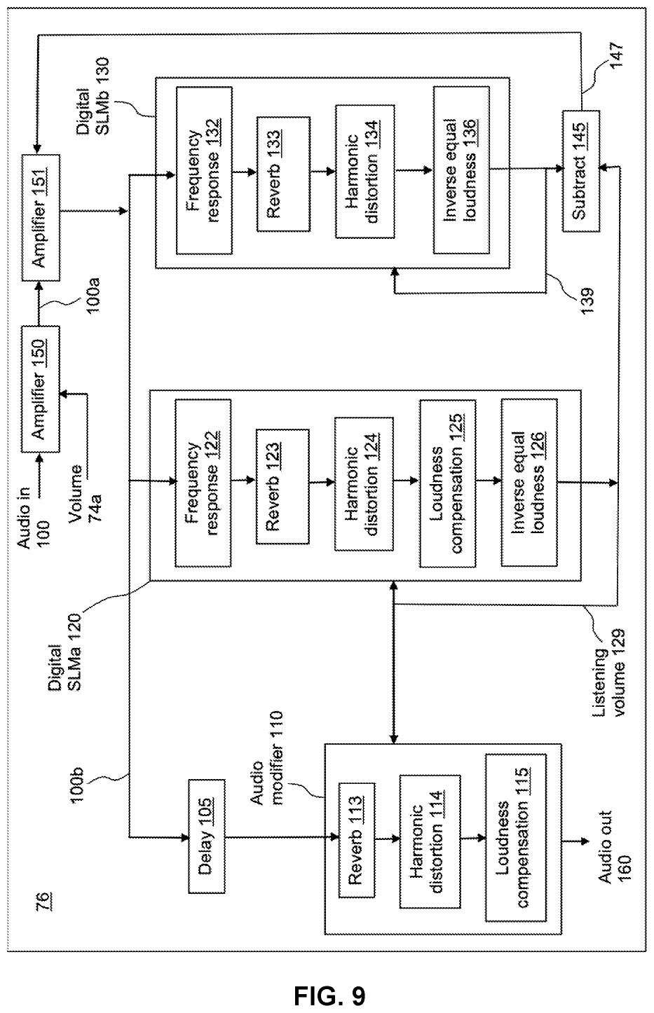

FIG. 9 shows a schematic block diagram of an alternate embodiment of the processor of the audio processing system of FIG. 8 and FIG. 3.

The figures are not to scale, and same or similar reference signs denote same or similar features.

An embodiment of the invention will now be described with reference to the flow diagram of FIG. 2, which shows the steps involved in the reception and modification of audio data in an audio processing system. The audio processing system may for example be an audio processing system in a computer, a mobile phone, a car stereo, or another similar audio playback apparatus. In a first step 10, the audio processing system receives audio data for processing. The audio data typically defines waveform(s) of variable frequency and amplitude, for generating sound when played back through an audio transducer such as a speaker, or pair of headphones. Multiple sound channels may be defined within the audio data, for example left and right stereo channels.

In step 20, the audio processing system receives a desired volume level, which would cause the sound to have a desired perceived frequency balance if the sound was played to a user at the desired volume level. The desired volume level may be specified by the user to be higher than the volume level at which the sound is actually played, for example if the user wishes to perceive the bass and treble of the audio data as though the sound was being played at the desired volume level, when the sound is actually being played at a lower volume level. In one embodiment, the user enters a value for the desired volume into the audio processing system, for example using a keyboard or touchscreen.

In another embodiment, the desired volume is received as metadata to the audio data, and may be embedded within an audio data signal that carries the audio data. The audio data signal may for example be defined in an audio data file that is stored in the audio processing system having the audio processing system, or stored on a computer readable medium that is read by the audio processing system, or the audio data signal may be streamed directly to the audio processing system from an external source such as a remote Internet server. The audio data signal may also be generated in real time, for example in the case of a computer game where various sound effects are encoded within the audio data signal as the game is played. The metadata typically specifies the desired volume level at which the sound encoded in the audio data file is intended by the producer to be played back at, to provide the correct perceived frequency balance.

In a step 30, the audio processing system obtains an equal loudness contour at the desired volume. The equal loudness contour at the desired volume defines how the sound defined by the audio data would be perceived by the user across the audible frequency range if the sound was played back at the desired volume. For example, if the desired volume is 90 dB (SPL), then the 90 Phon equal loudness contour shown in FIG. 1 according to ISO 226:2003 could be retrieved from a memory, corresponding to 90 dB (SPL) at 1 kHz. If the desired volume is 91 dB (SPL), then the 90 Phon and 100 Phon equal loudness contours of FIG. 1 could be retrieved from the memory and interpolated between to provide an equal loudness contour at 91 dB (SPL) at 1 kHz. Or, a mathematical model could be used to provide an equal loudness contour at any given SPL (Sound Pressure Level). In an alternate embodiment, the audio processing system or another apparatus is used to measure equal loudness contours that are specific to the user, and those equal loudness contours are selected, interpolated between, or used to base a mathematical model upon, to obtain the equal loudness contour at the desired volume.

In step 40, the listening volume is determined. The listening volume is the sound pressure level at which the user hears the sounds defined by the audio data. In this embodiment, the listening volume is the instantaneous sound pressure level and so is always varying with the loudness of the sound, but in alternative embodiments the listening volume may be the average sound pressure level of the sound or audio track being played. The listening volume depends on the position and orientation of the user, and even between each ear of the user, relative to the speakers (audio transducers), since the further away the user is from the audio transducers, the quieter the audio will be heard to be. Therefore, to determine the listening volume accurately, a calibration process is first carried out, as is described further below with reference to FIG. 8.

In step 50, the audio processing system obtains an equal loudness contour at the listening volume. The equal loudness contour at the listening volume defines how the various frequencies of the sounds defined by the audio data are being perceived relative to one another by the user during playback at the listening volume. The equal loudness contour at the listening volume is obtained in the same manner as described above for obtaining the equal loudness contour at the desired volume. If the user has the volume control of the audio playback system set so that the listening volume is lower than the desired volume, then the bass and treble frequencies need to be increased in amplitude relative to the mid frequencies of the audio data, in accordance with the difference between the equal loudness curves at the listening volume and at the desired volume, for the frequency balance to be perceived as though the audio data was being played back at the desired volume.

In step 60, the modification of the audio data based on difference between equal loudness contours at the desired and listening volumes is carried out. Then, when the modified audio data is played to the user, it is perceived with the same frequency balance as if the sound was played back at the desired volume rather than the listening volume.

The schematic diagram of FIG. 3 shows an audio processing system 75 for implementing the method of FIG. 2. The audio processing system 75 comprises an input for receiving an audio signal 70. In this embodiment, the audio signal 70 is a digital audio signal that is being streamed to the audio processing system from the Internet over a wireless network, however other types and sources of audio signal 70 may also be used. The audio signal 70 comprises audio data that encodes sounds for playback, and metadata specifying the desired volumes(s) at which the sounds are to be played back at. The audio processing system 75 comprises a processor 76 which receives the audio signal 70.

The audio processing system 75 is connected to a volume control 74, which the user can set to specify how loudly they wish to listen to the sound. The processor 76 receives a volume signal from the volume control 74, and outputs an audio signal 77 to a speaker 78. The audio signal 77 is amplified within the processor 76 according to the volume signal, and the speaker 78 produces audible sound for the user to listen to. The audio signal 77 may be an analogue audio signal, or a digital audio signal. In an alternate embodiment, the volume control 74 may also be connected to the speaker 78, for example if the speaker 78 is an active speaker that performs signal amplification. The speaker 78 may comprise a plurality of speakers that each respond to different parts of the audio signal 77, for example to implement a surround sound system, or left and right speakers of a set of headphones.

It will also be appreciated that in alternate embodiments the volume control 74 and the speakers 78 may be formed as part of the audio processing system 75 instead of being separate therefrom.

The processor 76 determines the listening volume produced by the speaker 78 based on the amplitude of the audio signal data in the audio signal 70 and the volume signal from the volume control 74, determines the desired volume from the metadata in the audio signal 70, and modifies the audio data to produce the audio signal 77 based on the difference between equal loudness contours at the listening and desired volumes. The desired volume could alternatively be specified to the audio processing system by an input from the user, instead of utilising any metadata on desired volume that may be present in the audio signal.

The graph shown in FIG. 4 illustrates modifications to be made to the audio data by the processor 76 in a case where the listening volume is lower than the desired volume. Specifically, the listening volume is determined to be 0 dB (SPL), and the desired volume is 100 dB (SPL). The trace 81a shows an equal loudness contour at the 0 dB (SPL) listening volume, and the trace 82a shows an equal loudness contour at the 100 dB (SPL) desired volume. The equal loudness contours are both referenced by their volumes at 1000 Hz. The trace 82a corresponding to the equal loudness contour at the 100 dB (SPL) desired volume is then subtracted from the trace 81a corresponding to the equal loudness contour at the 0 dB (SPL) listening volume, to produce the difference curve 83a. Since the desired volume is higher than the perceived volume, the lowest value in the difference curve between 1000 and 4000 Hz is identified and then the difference curve is translated upward to move that point to a gain of 0 dB (unity gain), providing a translated difference curve 84a.

The audio data is then amplified by the translated difference curve 84a across all the frequencies of the audio data to modify the audio data so that the frequency balance of the modified audio data at the 0 dB (SPL) listening volume will be perceived the same as the frequency balance that would be perceived if the unmodified audio data was played back at the 100 dB (SPL) desired volume. It can be seen that the translated difference curve has the effect of boosting the bass and treble frequencies of the audio data by up to 50 dB (SPL) at the extremes of the audible frequency range, whereas the mid frequencies of around 1000 to 4000 Hz are hardly modified at all.

The lowest value in the difference curve 83a between 1000 and 4000 Hz is selected for translating to 0 dB (unity gain) when forming the translated difference curve, since the human ear is most sensitive to those frequencies and so the perceived volume of the modified audio data will remain closer to the perceived volume of the unmodified audio data. In further refinements, the amplitude of the audio data may be altered until the perceived volume of the modified audio data becomes the same as the volume that would be perceived if the unmodified audio data was played, i.e. without amplification by the translated difference curve 84a.

The graph shown in FIG. 5 illustrates modifications to be made to the audio data by the processor 76 in a case where the listening volume is higher than the desired volume. Specifically, the listening volume is determined to be 10 dB (SPL), and the desired volume is 0 dB (SPL). The trace 81b shows an equal loudness contour at the 10 dB (SPL) listening volume, and the trace 82b shows an equal loudness contour at the 0 dB (SPL) desired volume. The equal loudness contours are both referenced by their volumes at 1000 Hz. The trace 82b corresponding to the equal loudness contour at the 0 dB desired volume is then subtracted from the trace 81b corresponding to the equal loudness contour at the 10 dB (SPL) listening volume, to produce the difference curve 83b. Since the desired volume is lower than the perceived volume, the highest value in the difference curve between 1000 and 4000 Hz is identified and then the difference curve is translated downward to move that point to a gain of 0 dB (unity gain), providing a translated difference curve 84b.

The audio data is then amplified by the translated difference curve 84b across all the frequencies of the audio data to modify the audio data so that the frequency balance of the modified audio data at the 10 dB (SPL) listening volume will be perceived the same as the frequency balance that would be perceived if the unmodified audio data was played back at the 0 dB (SPL) desired volume. It can be seen that the translated difference curve 84b has the effect of cutting the bass and treble frequencies of the audio data at the extremes of the audible frequency range, whereas the mid frequencies of around 1000 to 4000 Hz are hardly modified at all.

Similarly to the difference curve 83a, the highest value in the difference curve 83b between 1000 and 4000 Hz is selected for translating to 0 dB (unity gain) when forming the translated difference curve, since the human ear is most sensitive to those frequencies and so the perceived volume of the modified audio data will remain closer to the perceived volume of the unmodified audio data. Again, in further refinements the amplitude of the audio data may be altered until the perceived volume of the modified audio data becomes the same as the volume that would be perceived if the unmodified audio data was played, i.e. without amplification by the translated difference curve 84b.

The volume of the sound encoded by the audio data in the audio signal 70 will vary in time, for example one moment the audio data may encode a person speaking at normal volume and the next moment the audio data may encode an explosion at much higher volume. In the embodiment where the audio signal 70 comprises metadata specifying the desired volume, the metadata may specify a time-varying desired volume that follows the changes in the volume of the sound encoded by the audio data. For example, the metadata may specify a desired volume of 70 dB (SPL) for when the person is speaking, meaning the frequency balance of the sound would be perceived correctly if the audio data was played at a listening volume of 70 dB (SPL), and the metadata may specify a desired volume of 100 dB (SPL) for when the explosion occurs, meaning the frequency balance of the sound would be perceived correctly if the audio data was played at a listening volume of 100 dB (SPL). The difference between those desired volumes and the actual listening volumes that result from the user's playback system are used to determine the first and second equal loudness contours at any given portion of the audio data corresponding to a given moment in time. Alternatively, the metadata could simply specify an average desired volume, and the average listening volume may be chosen for comparison with the average desired volume, by comparing the first equal loudness contour at the average desired volume with the second equal loudness contour at the average listening volume. A hybrid between those schemes could also be implemented in alternate embodiments, where the desired and listening volumes at any given portion of the audio data corresponding to a moment in time are based on both the short-term (instantaneous) volume and the long-term (average) volume.

In an embodiment where the audio signal 70 does not include any metadata, or where the metadata is disregarded, the desired volume may be set as a fixed volume by the user. For example, the user may wish the frequency balance of the sound to be perceived in the way it would be if the sound was being listened to at a fixed volume, such as 85 dB (SPL). Therefore, the user sets the desired volume at 85 dB (SPL). Then, the frequency balance of the person speaking is modified to sound as though it would if the person speaking was played at 85 dB, and the frequency balance of the explosion is modified to sound as though it would if the explosion was played at 85 dB.

This can be visualised in the two graphs of FIG. 6, each of which show audio data with the perceived frequency balance on the vertical axis and time on the horizontal axis. The uppermost graph corresponds to the input audio signal 70 where the perceived frequency balance varies in time with changes in volume between 75 db (SPL) and 55 dB (SPL), and the lowermost graph shows the output audio signal 77 where the perceived frequency balance is now constant, as a result of the constant 85 dB (SPL) desired volume that has been set by the user. It will be understood that the volume of the output audio signal 70 still varies in time, but the perceived frequency balance is now as though the output audio signal 70 was fixed in volume at 85 dB (SPL). This mode of operation is referred to as a static mode, since the desired volume is static.

This setting of a static (fixed) desired volume may be sufficient for audio data whose instantaneous volume does not vary very much with time, for example some music tracks, or if the dynamic range of the perceived frequency balance perception is to be compressed. For audio data including large variations in volume such as the person speaking and the loud explosion, it may be desirable for the desired volume to vary in accordance with the variation in amplitude of the audio data, rather than being fixed at a specific level. In an alternate, improved embodiment, the user may set the desired volume to be a fixed amount higher than the listening volume, for example 20 dB (SPL). This situation can be visualised in the two graphs of FIG. 7, each of which show audio data with the perceived frequency balance on the vertical axis and time on the horizontal axis. The uppermost graph corresponds to the input audio signal 70 where the perceived frequency balance varies in time with changes in volume between 75 db (SPL) and 55 dB (SPL), and the lowermost graph shows the output audio signal 77 where the frequency balance is altered to be perceived as though it would be if the audio signal was being played back 20 dB (SPL) higher than it actually is, i.e. between 95 db (SPL) and 75 dB (SPL) instead of between 75 db (SPL) and 55 dB (SPL). This mode of operation is referred to as a dynamic mode, since the desired volume changes dynamically along with the listening volume.

A hybrid (smart) mode in a further embodiment may use a mixture of the static and dynamic modes, in which the desired volume is allowed to rise and fall relative to a fixed long-term average level, in time with the rise and fall in the listening volume.

The determination of the listening volume is an important step that needs to be taken in order to identify the correct second equal loudness contour, the second equal loudness contour being compared against the first equal loudness contour at the desired volume to determine the modifications that need to be made to the audio data. The listening volume in this embodiment is determined by a digital sound level meter 82 within the processor 76, as shown in FIG. 8. To provide an accurate listening volume, the digital sound meter is first calibrated using a microphone 84 at the listening position of the user, to help assure that the digital sound meter will correctly report the volume heard by the user. Specifically, the processor 76 provides an audio signal 80 to the digital sound meter 82 and the speaker 78. The speaker 78 generates sound 79, which is picked up by the microphone 84, and the microphone 84 feeds the audio back to the digital sound meter 82. The digital sound meter 82 calibrates itself based on the signal received from the microphone 84, to report the correct volume at the listening position. The audio signal 80 delivers a noise to the speaker 78 to calibrate the volume.

The measurement of the listening volume in this embodiment is further improved by calibrating the digital sound meter 82 to take account of how different frequencies are reproduced by the speaker 78. The listening volume perceived by the user depends on the frequencies contained within the sound, and the frequencies reproduced by the speaker 78 and propagated to the microphone 84 may be different from the frequencies in the audio signal 80, due to the particular capabilities of the speaker 78 or the room the speaker is in. Therefore, the accuracy of the digital sound meter can be improved by performing a frequency sweep across various frequencies to determine how well each frequency reaches the listening position. The calibration may also comprise playing the audio signal 80 at different volumes, to characterise the effects of reverberation and harmonic distortion with changing volume, which will also influence the frequency balance and therefore the perceived listening volume.

The calibration can also be further improved by using binaural microphones placed at the left and right ears of the user, instead of the microphone 84 at the listening position. Then, the digital sound meter 82 can be calibrated for the left and right ears of the user individually. It would also be possible for the microphone 84 to be incorporated as part of a physical sound level meter that included a filter corresponding to an inverted equal loudness curve, the inverted equal loudness curve being selected in consultation with the digital sound meter 82.

The digital sound meter 82 evaluates the perceived listening volume by applying the inverse of an equal loudness curve to the audio to be measured, where the equal loudness curve is selected to correspond to the perceived listening volume that was determined for a given portion of the audio data. The equal loudness curves are personalised to the specific user, and their characteristics stored in a memory of the processor 76. In this embodiment, the personalised equal loudness curves are determined by playing a variety of frequencies to the user and requiring the user to specify how loud each frequency needs to be played for all the frequencies to be perceived to have the same loudness. Alternatively, otoacoustic emission tests may be utilized to determine personalized equal loudness curves. During playback of the audio signal 70 (see FIG. 3), the frequency balance of the audio signal is also altered by the process of amplification by the translated difference curve, for example 84a or 84b. In embodiments where the digital sound meter 82 is configured to measure the audio signal 70 rather than the audio signal 77, the digital sound meter also needs to take into account the changes in frequency balance that occur due to the amplification by the translated difference curve. These changes may cause the audio signal 77 to be perceived up to 10 dB higher or lower in volume than the audio signal 70, depending on whether the desired volume is higher or lower than the listening volume, respectively.

In order to fully evaluate the perceived volume at the listening position, the digital sound meter 82 applies the following processes to the incoming audio signal 70:
1: Filtering the audio signal with an inverted equal loudness curve corresponding to an estimate of the listening volume.
2: Applying the translated difference curve to the audio signal.
3: Applying the harmonic distortion caused by the playback system at the listening position.
4: Applying the reverb caused by the room at the listening position.
5: Filtering the audio data by the frequency response of the playback system.

The sum of points 1-5 above produces a full emulation of the listening conditions at the listening position, which in turn provides the most accurate perceived volume. The digital sound meter 82 may only implement one or a selection of those steps 1 to 5, but preferably implements all of them. The order in which the steps are implemented may be different in alternate embodiments. The estimate of the listening volume may be determined recursively, starting from an estimate based on the listening volume determined for a given portion of the audio data, going through steps 1 to 5 to determine a second estimate of the listening volume, and using that second estimate to repeat steps 1 to 5 again. One possible implementation of the processor 76 will now be described with reference to FIG. 9. The parts of the processor 76 used in calibration of the digital sound meter 82 and in determining the desired volume (e.g. from metadata or user input) are not shown in FIG. 9 for the sake of clarity. As shown, the processor comprises an amplifier 150 that receives audio data 100, for example audio data provided to the processor in the input audio signal 70 of FIG. 3. The amplifier 150 amplifies the audio data by an amount based on a volume control signal 74a, which is received from the user volume control 74 of FIG. 3. The amplifier 150 outputs the amplified audio signal 100a to a further amplifier 151 of the processor 76. The further amplifier 151 amplifies the audio data 100a by an amount based on a control signal 147, to provide amplified audio data 100b. The amplified audio data 100b is passed to three processing units that operate on the amplified audio data 100b in parallel to one another, the processing units being an audio modifier 110, a digital sound meter 120, and a digital sound meter 130. The audio modifier 110 receives the amplified audio data 100b and modifies the frequency balance of the audio data 100b to that which would be perceived if the audio data was played back at the desired volume, rather than the current listening volume. The audio modifier 110 comprises a reverb block 113, a harmonic distortion block 114, and a loudness compensation block 115. The reverb block 113 increases or decreases reverberation of the audio data based on the difference between the listening volume 129 and the desired volume, and the harmonic distortion block 114 increases or decreases harmonic distortion of the audio data based on the difference between the listening volume 129 and the desired volume. The changes in reverb and harmonic distortion are also based on the calibration of the audio playback system described with reference to FIG. 8, for example if the room is very echoey then a larger amount of reverb compensation will be applied, and if the playback system suffers from larger harmonic distortions as the volume increases then a larger amount of harmonic distortion will be applied to the audio data, to help make the frequency balance be perceived as it would be if the audio data was being played back at the desired volume rather than the listening volume.

Following the reverb and harmonic distortion blocks, the loudness compensation block 115 modifies the audio data based on the difference between the equal loudness curves at the listening and desired volumes, as described previously with reference to FIGS. 4 and 5. The audio modifier 110 outputs the audio data from the loudness compensation block 115 as output audio 160, which is carried in output audio signal 77 marked on FIG. 3. The digital sound meter 120 is an implementation of the digital sound meter 82 of FIG. 8, and is designed to determine the listening volume 129 at the listening position of the user, which is sent to the audio modifier 110. The audio data 100b received by the audio modifier 110 is slightly delayed by delay block 105, compared to the audio data 100b received by the digital sound meter 120. Accordingly, the digital sound meter 120 has time to determine the listening volume of a particular portion of audio before that listening volume is required in the audio modifier 110.

The digital sound meter 120 has been calibrated according to the calibration processes described in relation to FIG. 8, and comprises a frequency response block 122 that emulates the effect on the audio of the frequency response of the playback system (primarily the speaker(s)), a reverb block 123 that emulates the effect on the audio of the room the speaker(s) are in, a harmonic distortion block 124 that emulates the harmonic distortion introduced by the playback system, a loudness compensation block 125 that compensates the audio in the same manner as the loudness compensation block 115, and an inverse equal loudness block 126 that filters the audio signal by the inverse of an equal loudness contour corresponding to an estimate of the listening volume, to finally give the listening volume. The listening volume 129 is fed back into the digital sound meter 120 to serve as an estimate of the listening volume that will exist in a later portion of the audio data, to allow selection of an equal loudness contour to be applied in the equal loudness block 126 at that portion. Since the loudness compensation applied by the loudness compensation blocks 115 and 125 will change the frequency balance of the audio data and therefore the perceived volume of the sounds played, the processor 76 further comprises the digital sound meter 130 to counteract the change in perceived volume that occurs when the audio modifier 110 is activated. The digital sound meter 130 comprises a frequency response block 132, a reverb block 133, a harmonic distortion block 134, and inverse equal loudness block 136, all similar to the corresponding blocks of the digital sound meter 120. However, unlike the digital sound meter 120, the digital sound meter 130 lacks a loudness compensation block. Therefore, the digital sound meter 130 produces a listening volume 139 corresponding to the volume the user would hear if the loudness compensation was not being applied. A subtract block 145 subtracts the listening volume 129 from the listening volume 139, to give the control signal 147. If the listening volume 129 rises relative to the listening volume 139, typically as a result of the desired volume increasing higher than the listening volume 129, then the control signal 147 will decrease, decreasing the amount of amplification performed by the amplifier 151 and bringing the perceived volume of the sound at the listening position back towards its perceived volume before any loudness compensation had been implemented. The left and right sound channels are processed by the processor 76 independently from one another, based on individual left and right channel calibrations, and individual left and right channel equal loudness curves personalised to the left and right ears of the listener. Further sound channels could also be processed independently from one another by the processor 76 in multi-channel sound systems if desired. The listening volume, desired volume, and equal loudness contours described herein are all referenced to sound pressure level at 1 kHz, by convention, but could all be referenced to sound pressure level at a different frequency if desired without affecting the operation of the invention. Many other variations of the described embodiments falling within the scope of the invention will be apparent to those skilled in the art. Whilst audio playback has been described as taking place through speakers, other types of audio transducer such as surface vibration transducers or bone conduction transducers could alternatively be used. An additional aspect of the present invention that could be implemented in combination with the embodiments described above is the incorporation of a camera device with a field of view directed at the listening position and configured to send image data to the audio processing system to allow the audio processing system to track the position of a listening user, assign coordinates in space to the user position relative to one or more transducers that the user is listening to, and adjust the modified audio based on the determination, for example by applying a dB offset to the modified audio. In some examples a depth camera may be used. A depth camera is able to measure: sideways movement of an object in the camera field of view, depth of the object in a predefined 3 dimensional space, and the height of the object in the same space. The determination of the object position can either be made by the camera device itself, or by a processor in the audio processing system once the image data from the camera has been received. Either way, this enables the audio processing system to determine where a user's head, and in particular where the user's left and right ears, is located within a 3-dimensional space. If the position of the transducers relative to the ears is also calculated then changes in the user's listening position can be compensated in real time by applying an offset to the modified audio. When the calibration at the listening position is performed the level in dB at the listening position is determined and stored. This dB value is associated with the listening position coordinates in 3 dimensional space (height X, depth Y, width Z) in relation to the camera's position. The term width as used herein may refer to the distance of the sides of the user's face relative to the center of the field of view of the camera. Each transducer position (X,Y,Z) in relation to the camera's position must be known, and can either be determined beforehand by manual measurement or determined automatically by methods known to those skilled in the art such as commercially available smartphone applications. Alternatively such distances could be determined via methods similar to sonar, inducing each transducer to emit a click sound and measuring the time elapsed between the audio played and the sound recorded by a microphone at the camera's position. The time elapsed between the digital audio played and the recorded audio can be used to calculate the distance between the transducer and the camera's position. Once the relative positions of the transducers and the camera have been determined, the processor will be able to determine a user's head and ear positions relative to each transducer based on the received image data from the camera. Once this information has been obtained the listening level at any point within the camera's field can be determined and compensated for. The loudness compensation applied by the present invention can be further personalised with this additional information about the position of the user's ears relative to each transducer. Since each ear perceives loudness and frequency differently, different loudness compensations can be calculated and applied for the left and right sides. For example, in a stereo system the left speaker could be calibrated for the left ear and the right speaker calibrated for the right ear.

Even more information about the listening level can be obtained if orientation is taken into account. For example, a triangulation operation can be carried out to calibrate the audio system using three microphones mounted at the listening position. This one time calibration at the listening position allows the audio processing system to not only determine how distant a transducer is from the listening position but also the orientation of that transducer on the horizontal plane in relation to the current user position. Triangulation using sound is well known to those skilled in the art and will not be elaborated on further herein. As mentioned above, the additional information obtained about the user position relative to each transducer allows for even more finetuned filtering of the frequency and volume of played audio, since it is possible to derive how the sound pressure level emitted by each transducer will change for the user's change in position. It should be emphasised that two calibrations must be carried out for each transducer in the system, one calibration for each ear, for the benefit of this embodiment to be achieved. At a basic level it is of course true that the dB level for a given transducer in a given ear of the user will drop as the ear of the user moves away from the transducer, and will increase as the ear of the user moves closer to the transducer. Thus if the user is moving from left to right then an offset should be applied decreasing the dB level of the modified audio output by the left speaker of a stereo system while an equivalent increase offset should be applied to the right speaker of the stereo system. An example formula that may be used for a more accurate calculation of the sound pressure level variation due to the difference in distance of listening positions, e.g. left and right ears, relative to a single sound source, e.g. transducer, is as follows:

$${L}_{2} = {L}_{1} - \vert 20 \cdot log ( \frac{{r}_{1}}{{r}_{2}} ) \vert$$

$${L}_{2} = {L}_{1} - \vert 10 \cdot {log ( \frac{{r}_{1}}{{r}_{2}} )}^{2} \vert$$

$${r}_{2} = {r}_{1} \cdot {10}^{( \frac{\vert {L}_{1} - {L}_{2} \vert}{20} )}$$

$${r}_{1} = \frac{{r}_{2}}{{10}^{( \frac{\vert {L}_{1} - {L}_{2} \vert}{20} )}}$$

Wherein L_[1] is the sound pressure level measured at a first distance r_[1] from the sound source and L_[2] is the sound pressure level measured at a second distance r_[2] form the sound source. L_[1] and L_[2] are measured in dB and r_[1] and r_[2] are measured in metres.

Using such calculations as determined based on the calibrations and the image data of the user position received from the camera, the audio processing can calculate an offset value (+/−dB) to be added or subtracted to the dB value produced by the digital sound meter post weighting filter. The same concept can be extended from stereo systems to multichannel processing systems such as surround speaker arrays (5.1/7.1 ecc.).

1. A method of processing audio data for playback, the method comprising: receiving audio data defining a sound within a plurality of frequency bands;
obtaining a first equal loudness contour at a desired volume, the desired volume corresponding to a desired perceived frequency balance of the sound when listened to by a user;
determining a listening volume at which the user listens to the sound using a digital sound meter having been calibrated based on a user listening position;
obtaining a second equal loudness contour at the listening volume;
modifying the frequency balance of the audio data based on the difference between the first and second equal loudness contours in each frequency band, such that playing the audio data at the listening volume will cause the user to perceive the frequency balance of the sound to be as though the sound was being played at the desired volume; and outputting the modified audio data.

2. The method of claim 1, wherein modifying the frequency balance of the audio data based on the difference between the first and second equal loudness contours in each frequency band comprises determining the difference between the first and second equal loudness contours at each of the frequency bands to produce a difference curve across the plurality of frequency bands; translating the difference curve towards a gain of one at a minimum or maximum point of the difference curve;
and amplifying the audio data by the value of the translated difference curve at each frequency band to provide the modified audio data.

3. The method of claim 1, wherein determining the listening volume comprises determining a volume of an audio signal in an audio processing system using a digital sound meter and calibrating the digital sound meter to determine the listening volume based on the volume of the audio signal.

4. The method of claim 3, wherein the calibration comprises playing noise having a known frequency spectrum through the audio processing system, monitoring the volume of the noise that is produced using a microphone, and storing a relationship between the listening volume picked up by the microphone and the volume of the audio signal measured by the digital sound meter, the audio signal carrying the noise.

5. The method of claim 3, wherein the calibration comprises playing a selection of frequencies through the audio processing system, monitoring the volumes of the sounds that are
produced using the microphone, and storing a frequency response of the audio processing system.

6. The method of claim 3, wherein the calibration is performed for the sounds produced by each individual audio transducer of the audio processing system.

7. The method of claim 1, further comprising determining equal loudness contours that are personal to the user, and storing the equal loudness contours in a memory, wherein the first and second equal loudness contours are obtained based on the equal loudness contours in the memory.

8. The method of claim 7, wherein the equal loudness contours personal to the user are determined by performing otoacoustic emission tests on the user, or by for each equal loudness curve playing sounds of different frequencies to the user and receiving user input on which volumes the sounds need to be played at to have a same loudness as one another.

9. The method of claim 1, further comprising modifying the audio data by increasing at least one of reverberation and harmonic distortion by an amount based on a volume difference from the listening volume to the desired volume.

10. The method of claim 1, wherein the audio data comprises metadata specifying the desired volume, the desired volume being a volume at which the creator of the audio data intends the sound to be played.

11. The method of claim 10, wherein the audio data defines a plurality of sounds mixed for simultaneous playback, and wherein the metadata comprises desired volumes for respective ones of the plurality of sounds.

12. The method of claim 1, further comprising receiving the desired volume as an absolute volume level, or as an offset in volume level above or below the determined listening volume.

13. The method of claim 1, wherein the listening volume is a perceived listening volume, and wherein determining the listening volume comprises filtering the audio data by the inverse of an equal loudness contour.

14. (canceled)

15. The method of claim 1, wherein the listening volume is the instantaneous volume of the sound listened to by the user, the listening volume varying over time in correspondence with the loudness of the sound defined by the audio data in each moment of time, and wherein determining the listening volume comprises analysing an amplitude of the audio data and determining the time-varying listening volume in accordance with the time-varying amplitude of the audio data.

16. (canceled)

17. (canceled)

18. (canceled)

19. A method according to claim 1, wherein the step of determining a listening volume at which the user listens to the sound further comprises detecting a user with a depth camera, determining the position of the user relative to the position of one or more transducers which the user is listening to, assigning three-dimensional coordinates to the position of the user, determining that a user is at a different position to the position for which the digital sound meter was calibrated and, applying an offset to the modified audio data to compensate the difference in position.

20. An audio processing system comprising:
an input for receiving audio data defining a sound within a plurality of frequency bands;
a processor configured to:
obtain a first equal loudness contour at a desired volume, the desired volume corresponding to a desired perceived frequency balance of the sound when listened to by a user;
determine a listening volume at which the user listens to the sound;
obtain a second equal loudness contour at the listening volume; and
modify the frequency balance of the audio data based on the difference between the first and second equal loudness contours in each frequency band, such that playing the audio data at the listening volume will cause the user to perceive the frequency balance of the sound to be as though the sound was being played at the desired volume; and
an output for outputting the modified audio data.

21. An audio processing system according to claim 20, further comprising a depth camera configured to detect the user, and wherein the processor is further configured to determine the position of the user relative to the position of one or more transducers which the user is listening to, assign three-dimensional coordinates to the position of the user and, applying an offset to the modified audio data to compensate for the user position.

22. (canceled)

23. (canceled)

24. (canceled)

25. An audio processing system comprising an input for receiving audio data defining a sound, a volume control for setting a volume of the sound to be played back, and a digital sound meter for determining a perceived listening volume of the sound based on the audio data and the volume control setting, wherein the digital sound meter is configured to determine the perceived listening volume of the sound based on the audio data and the volume control setting for each portion of the audio data by dividing the audio data into identical first and second streams, applying a delay to the first stream, determining an equal loudness contour for the portion of audio data in the second stream during the delay, and filtering the portion of the audio data by the inverse of an equal loudness contour at the listening volume that was determined for the second stream.

26. The audio processing system of claim 25, wherein the equal loudness contour and perceived listening volume are determined recursively, the recursion comprising filtering a portion of the audio data by an inverse of a first estimated equal loudness contour to provide a first perceived listening volume, selecting a second estimated equal loudness contour corresponding to the first perceived listening volume, and filtering the portion of the audio data by an inverse of the second estimated equal loudness contour to provide a second perceived listening volume.

27. The audio processing system of claim 25, wherein the equal loudness contour is an equal loudness contour corresponding to the sense of hearing of an individual user of the audio processing system.
